(19) United States
(12) Patent Application Publication
(10) Pub. No.: US 2024/0284707 A1
(43) Pub. Date: Aug. 22, 2024

(54) DISPLAY DEVICE AND METHOD OF MANUFACTURING DISPLAY DEVICE

(71) Applicant: Sharp Display Technology Corporation, Kameyama City , Mie (JP)

(72) Inventors: Takao SAITOH, Kameyama City , Mie (JP); Yohsuke KANZAKI, Kameyama City , Mie (JP); Masaki YAMANAKA, Kameyama City , Mie (JP); Masahiko MIWA, Kameyama City , Mie (JP); Yi SUN, Kameyama City , Mie (JP); Masaki FUJIWARA, Kameyama City , Mie (JP)

(21) Appl. No.: 18/571,663

(22) PCT Filed: Aug. 6, 2021
(86) PCT No.: PCT/JP2021/029323

§ 371 Date: Dec. 18, 2023

(51) Int. Cl. H10K 59/121; H10K 59/12; H10K 59/80

(52) U.S. Cl. CPC H10K 59/1213; H10K 59/1201; H10K 59/1216; H10K 59/873

(57) ABSTRACT

A second TFT includes: a second semiconductor layer of an oxide semiconductor; a second interlayer insulating film covering the second semiconductor layer; a terminal electrode; and a contact hole exposing at least a part of the second semiconductor layer. A metal layer is provided covering an exposed surface of the second semiconductor layer exposed inside the contact hole. The terminal electrode is electrically connected to the second semiconductor layer via the contact hole and the metal layer.

### TECHNICAL FIELD

The disclosure relates to display devices and methods of manufacturing display devices.

### BACKGROUND ART

The organic EL display device, or the self-luminous display device built around organic electroluminescence elements (hereinafter, may be referred to as “organic EL elements”), has been attracting attention as a promising successor to the liquid crystal display device. The organic EL display device includes a plurality of thin film transistors (hereinafter, may be referred to as “TFTs”) in each subpixel that provides a minimum unit of images. Well-known examples of a semiconductor layer in such a TFT include a semiconductor layer of a polysilicon that exhibits high mobility and a semiconductor layer of an oxide semiconductor such as In—Ga—Zn—O that causes small leakage current.

As an example, Patent Literature 1 discloses a display device including inverted staggered TFTs (bottom-gate structure) with a buffer layer between an oxide semiconductor and source and drain electrode layers.

### CITATION LIST

### Patent Literature

Patent Literature 1: Japanese Unexamined Patent Application Publication, Tokukai, No. 2016-96347

### SUMMARY

### Technical Problem

A display device has been proposed that has a hybrid structure in which polysilicon semiconductor-based TFTs and oxide semiconductor-based TFTs are both formed on a substrate.

In such a display device, contact holes are provided to electrically connect either a semiconductor layer of a polysilicon or a semiconductor layer of an oxide semiconductor to a source electrode and a drain electrode. Each contact hole is formed by patterning an inorganic insulating film in the TFT by, for example, dry etching. The polysilicon semiconductor-based TFT is subjected to hydrofluoric-acid (HF) rinsing in order to remove a surface oxide film from the part of the polysilicon film that is exposed in a bottom portion of the contact hole, after the patterning of the inorganic insulating film, but before the formation of the source and drain electrodes. This hydrofluoric-acid rinsing ensures the formation of contact holes that reach the semiconductor layer of a polysilicon, thereby reducing contact resistance between this semiconductor layer and the source and drain electrodes.

In the hydrofluoric-acid rinsing, the hydrofluoric-acid rinsing solution comes into contact also with the surface of the oxide semiconductor film that is exposed in a bottom portion of other contact holes. The hydrofluoric-acid rinsing solution erodes the oxide semiconductor film, and for this reason, the oxide semiconductor-based TFT could in the hydrofluoric-acid rinsing suffer from manufacturing defects such as oxide semiconductor deficiency and breaks in the oxide semiconductor pattern.

The disclosure has been made in view of these issues and has an object to restrain manufacturing defects caused in the oxide semiconductor-based TFTs by hydrofluoric-acid rinsing.

### Solution to Problem

To achieve the object, a display device in accordance with the disclosure includes: a substrate; and a thin film transistor layer on the substrate, the thin film transistor layer including, in each subpixel: a first thin film transistor including a first semiconductor layer of a polysilicon; and a second thin film transistor including a second semiconductor layer of an oxide semiconductor, wherein the second thin film transistor includes: the second semiconductor layer on a first interlayer insulating film farther away from the substrate than is the first semiconductor layer; a second interlayer insulating film covering the second semiconductor layer; a terminal electrode; and a contact hole exposing at least a part of the second semiconductor layer, a metal layer is provided covering an exposed surface of the second semiconductor layer exposed inside the contact hole, and the terminal electrode is electrically connected to the second semiconductor layer via the contact hole and the metal layer.

A method of manufacturing a display device in accordance with the disclosure is a method of manufacturing a display device including: a substrate; and a thin film transistor layer on the substrate, the thin film transistor layer including, in each subpixel: a first thin film transistor including a first semiconductor layer of a polysilicon; and a second thin film transistor including a second semiconductor layer of an oxide semiconductor, the method including: a second semiconductor layer formation step of forming the second semiconductor layer on a first interlayer insulating film farther away from the substrate than is the first semiconductor layer; a second interlayer insulating film formation step of forming a second interlayer insulating film covering the second semiconductor layer; a contact hole formation step of forming a contact hole exposing at least a part of the second semiconductor layer; a metal layer formation step of forming a metal layer covering an exposed surface of the second semiconductor layer exposed inside the contact hole, by forming a metal film on the second interlayer insulating film through which the contact hole has been formed and subsequently patterning the metal film; and a terminal electrode formation step of forming a terminal electrode electrically connected to the second semiconductor layer via the contact hole and the metal layer.

### Advantageous Effects of Disclosure

The disclosure can restrain manufacturing defects caused in the oxide semiconductor-based TFTs by hydrofluoric-acid rinsing.

### BRIEF DESCRIPTION OF DRAWINGS

FIG. 1 is a schematic plan view of a structure of an organic EL display device in accordance with a first embodiment of the disclosure.

FIG. 2 is a plan view of a display area of the organic EL display device in accordance with the first embodiment of the disclosure.

FIG. 3 is a cross-sectional view of the display area of the organic EL display device in accordance with the first embodiment of the disclosure.

FIG. 4 is an enlarged cross-sectional view of a second TFT and the surroundings thereof in a TFT layer that is a part of the organic EL display device in accordance with the first embodiment of the disclosure.

FIG. 5 is an equivalent circuit diagram of the organic EL display device in accordance with the first embodiment of the disclosure.

FIG. 6 is a cross-sectional view of an organic EL layer that is a part of the organic EL display device in accordance with the first embodiment of the disclosure.

FIG. 7 is an enlarged cross-sectional view, which is an equivalent of FIG. 4, of a second TFT and the surroundings thereof in a TFT layer that is a part of an organic EL display device in accordance with a second embodiment of the disclosure.

FIG. 8 is an enlarged cross-sectional view, which is an equivalent of FIG. 4, of a second TFT and the surroundings thereof in a variation example of the TFT layer that is a part of the organic EL display device in accordance with the second embodiment of the disclosure.

FIG. 9 is an enlarged cross-sectional view, which is an equivalent of FIG. 4, of a second TFT and the surroundings thereof in a TFT layer that is a part of an organic EL display device in accordance with a third embodiment of the disclosure.

FIG. 10 is an enlarged cross-sectional view, which is an equivalent of FIG. 4, of a second TFT and the surroundings thereof in a variation example of the TFT layer that is a part of the organic EL display device in accordance with the third embodiment of the disclosure.

### DESCRIPTION OF EMBODIMENTS

The following will describe in detail embodiments of the disclosure with reference to drawings. Note that the disclosure is not limited to the embodiments.

### First Embodiment

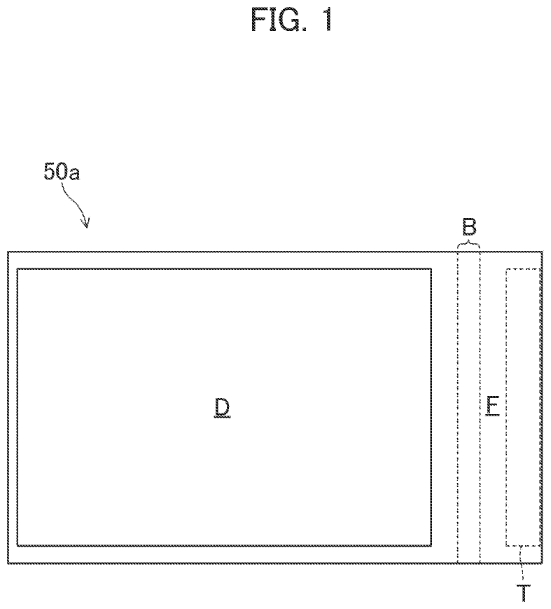

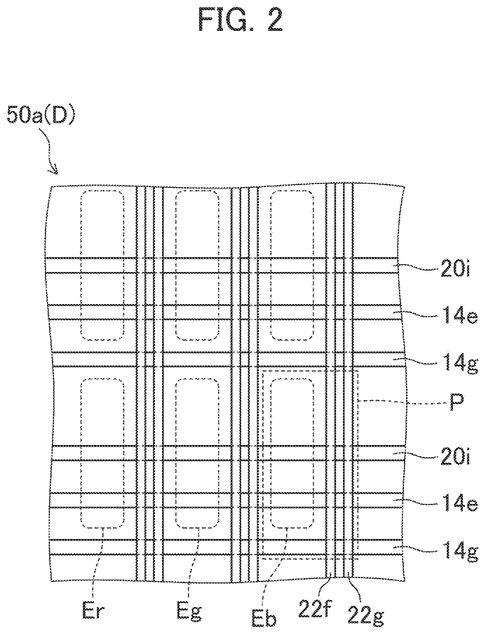

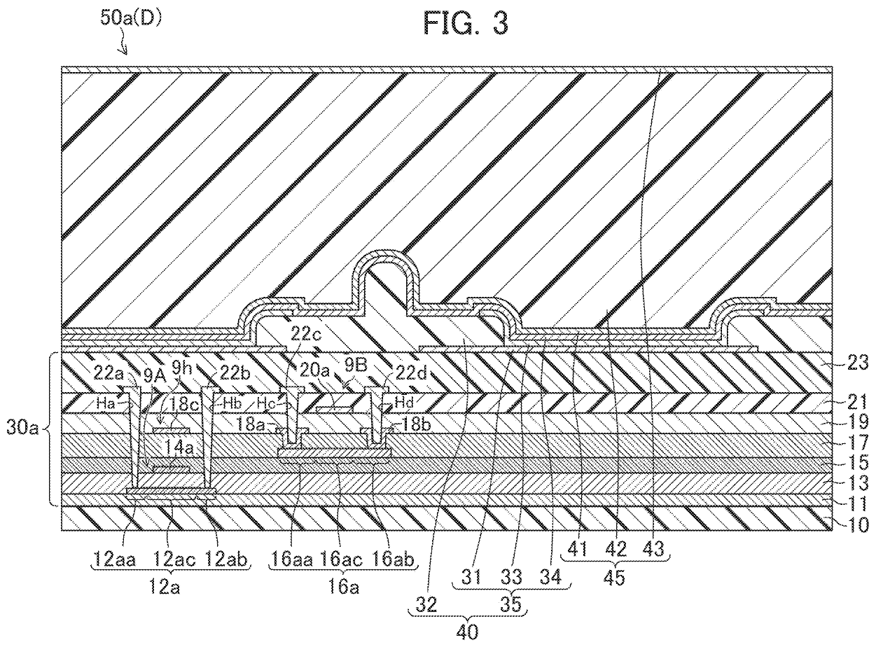

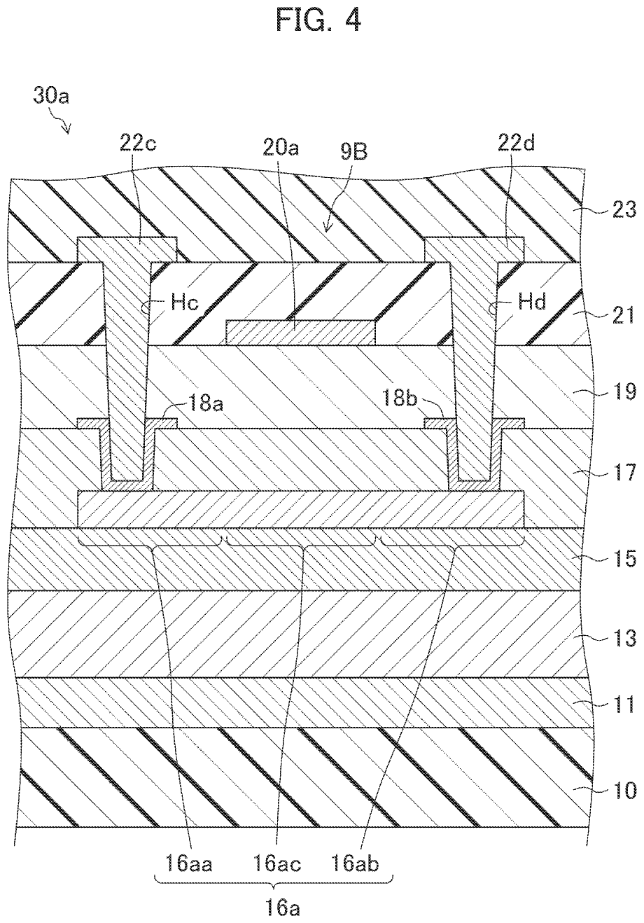

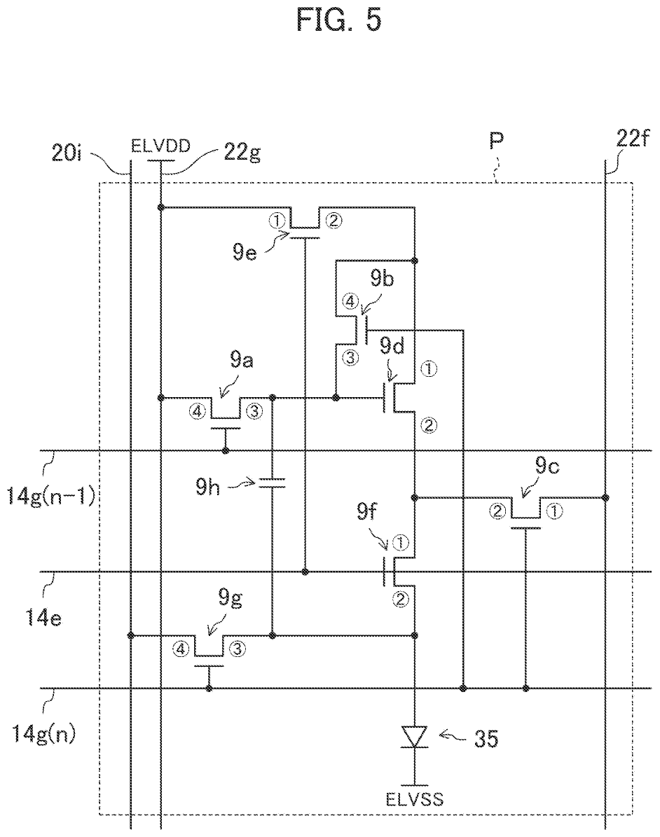

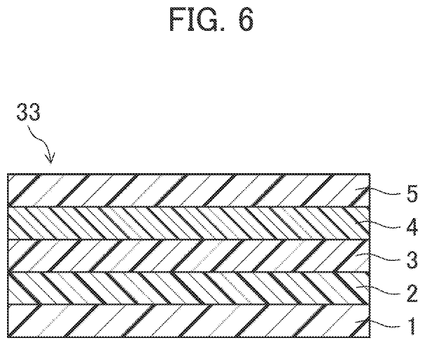

FIGS. 1 to 6 illustrate a first embodiment of the display device in accordance with the disclosure. Note that each embodiment below will discuss an organic EL display device including organic EL elements as an example of a display device including light-emitting elements. Here, FIG. 1 is a schematic plan view of a structure of an organic EL display device 50a in accordance with the present embodiment. FIGS. 2 and 3 are a plan view and a cross-sectional view, respectively, of a display area D of the organic EL display device 50a. FIG. 4 is an enlarged cross-sectional view of a second TFT 9B and the surroundings thereof in a TFT layer 30a that is a part of the organic EL display device 50a. FIG. 5 is an equivalent circuit diagram of the organic EL display device 50a. FIG. 6 is a cross-sectional view of an organic EL layer 33 that is a part of the organic EL display device 50a.

Referring to FIG. 1, the organic EL display device 50a has, for example, the rectangular display area D for producing image displays and a frame area F shaped like a frame surrounding the display area D. Note that the present embodiment gives the rectangular display area D as an example. This rectangular shape encompasses, for example, generally rectangular shapes such as those with a curved side(s), those with a round corner(s), and those with a notched side(s).

There is provided a matrix of subpixels P in the display area D as shown in FIG. 2. In addition, in the display area D, for example, a subpixel P including a red-light-emission region Er for a display in red, a subpixel P including a green-light-emission region Eg for a display in green, and a subpixel P including a blue-light-emission region Eb for a display in blue are provided adjacent to each other as shown in FIG. 2. Note that each pixel in the display area D is formed by, for example, three adjacent subpixels P including a red-light-emission region Er, a green-light-emission region Eg, and a blue-light-emission region Eb.

The frame area F includes a terminal section T along the far right side of the frame area F as in FIG. 1. In addition, the frame area F further includes a bending portion B extending in one direction (in the vertical direction in the drawing) between the display area D and the terminal section T as shown in FIG. 1. The bending portion B can be bent 180° around the vertical direction in the drawing (to form a U-shape).

Referring to FIG. 3, the organic EL display device 50a includes: a resin substrate 10 as a base-providing substrate (base substrate); the TFT layer 30a on the resin substrate 10; an organic EL element layer 40 as a light-emitting element layer on the TFT layer 30a; and a sealing film 45 covering the organic EL element layer 40.

The resin substrate 10 is made of, for example, a polyimide resin.

Referring to FIG. 3, the TFT layer 30a includes: a base coat film 11 on the resin substrate 10; four first TFTs 9A, three second TFTs 9B, and one capacitor 9h, all on the base coat film 11, in each subpixel P; and a planarization film 23 on the first TFTs 9A, the second TFTs 9B, and the capacitor 9h. Here, the TFT layer 30a includes a plurality of gate lines 14g extending parallel to each other in the horizontal direction in the drawing, as shown in FIG. 2. In addition, the TFT layer 30a includes a plurality of light-emission control lines 14e extending parallel to each other in the horizontal direction in the drawing, as shown in FIG. 2. In addition, the TFT layer 30a includes a plurality of second initialization power supply lines 20i extending parallel to each other in the horizontal direction in the drawing, as shown in FIG. 2. Note that each light-emission control line 14e is provided adjacent to an associated one of the gate lines 14g and an associated one of the second initialization power supply lines 20i as shown in FIG. 2. In addition, the TFT layer 30a includes a plurality of source lines 22f extending parallel to each other in the vertical direction in the drawing as shown in FIG. 2. In addition, the TFT layer 30a includes a plurality of power supply lines 22g extending parallel to each other in the vertical direction as shown in FIG. 2. Note that each power supply line 22g is provided adjacent to an associated one of the source lines 22f as shown in FIG. 2.

Referring to FIG. 3, each first TFT 9A includes: a first semiconductor layer 12a on the base coat film 11; a gate insulating film 13 covering the first semiconductor layer 12a; a first gate electrode 14a on the gate insulating film 13; a first interlayer insulating film 15 covering the first gate electrode 14a; a second interlayer insulating film 17, a third interlayer insulating film 19, and a fourth interlayer insulating film 21 sequentially provided on the first interlayer insulating film 15; and a first terminal electrode 22a and a second terminal electrode 22b at a distance from each other on the fourth interlayer insulating film 21.

The base coat film 11, the gate insulating film 13, the first interlayer insulating film 15, the second interlayer insulating film 17, the third interlayer insulating film 19, and the fourth interlayer insulating film 21 each include, for example, either a monolayer film of, for example, silicon nitride, silicon oxide, or silicon oxynitride or a stack of any of these films.

The first semiconductor layer 12a contains, for example, a polysilicon such as LTPS (low temperature polysilicon) and includes: a first conductive region 12aa and a second conductive region 12ab at a distance from each other; and a first channel region 12ac between the first conductive region 12aa and the second conductive region 12ab, as shown in FIG. 3.

The first gate electrode 14a overlaps the first channel region 12ac of the first semiconductor layer 12a and controls conduction between the first conductive region 12aa and the second conductive region 12ab of the first semiconductor layer 12a, as shown in FIG. 3.

The first terminal electrode 22a and the second terminal electrode 22b are electrically connected respectively to the first conductive region 12aa and the second conductive region 12ab of the first semiconductor layer 12a via a first contact hole Ha and a second contact hole Hb formed through the stack of the gate insulating film 13, the first interlayer insulating film 15, the second interlayer insulating film 17, the third interlayer insulating film 19, and the fourth interlayer insulating film 21, as shown in FIG. 3.

Referring to FIGS. 3 and 4, each second TFT 9B includes: a second semiconductor layer 16a on the first interlayer insulating film 15; the second interlayer insulating film 17 covering the second semiconductor layer 16a; the third interlayer insulating film 19 on the second interlayer insulating film 17; a second gate electrode 20a on the third interlayer insulating film 19; the fourth interlayer insulating film 21 covering the second gate electrode 20a; and a third terminal electrode 22c and a fourth terminal electrode 22d at a distance from each other on the fourth interlayer insulating film 21.

The second semiconductor layer 16a contains, for example, an oxide semiconductor such as an In—Ga—Zn—O-based semiconductor and includes: a third conductive region 16aa and a fourth conductive region 16ab at a distance from each other; and a second channel region 16ac between the third conductive region 16aa and the fourth conductive region 16ab, as shown in FIGS. 3 and 4. The second semiconductor layer 16a is disposed farther away from the resin substrate 10 than is the first semiconductor layer 12a as shown in FIG. 3. Here, the In—Ga—Zn—O-based semiconductor is a ternary oxide of In (indium), Ga (gallium), and Zn (zinc), and the proportion (composition ratio) of In, Ga, and Zn is not limited in any particular manner. In addition, the In—Ga—Zn—O-based semiconductor may be either amorphous or crystalline. Note that a preferred In—Ga—Zn—O-based crystalline semiconductor is an In—Ga—Zn—O-based crystalline semiconductor in which the c axis is oriented substantially perpendicularly to the layer plane. The second semiconductor layer 16a may contain an alternative oxide semiconductor in place of the In—Ga—Zn—O-based semiconductor. The alternative oxide semiconductor may be, for example, an In—Sn—Zn—O-based semiconductor (e.g., In₂O₃—SnO₂—ZnO; InSnZnO). Here, the In—Sn—Zn—O-based semiconductor is a ternary oxide of In (indium), Sn (tin), and Zn (zinc). In addition, the second semiconductor layer 16a may contain another oxide semiconductor including In—Al—Zn—O-based semiconductor, In—Al—Sn—Zn—O-based semiconductor, Zn—O-based semiconductor, In—Zn—O-based semiconductor, Zn—Ti—O-based semiconductor, Cd—Ge—O-based semiconductor, Cd—Pb—O-based semiconductor, CdO (cadmium oxide), Mg—Zn—O-based semiconductor, In—Ga—Sn—O-based semiconductor, In—Ga—O-based semiconductor, Zr—In—Zn—O-based semiconductor, Hf—In—Zn—O-based semiconductor, Al—Ga—Zn—O-based semiconductor, Ga—Zn—O-based semiconductor, In—Ga—Zn—Sn—O-based semiconductor, InGaO₃ (ZnO)₅, magnesium zinc oxide (MgₓZn₁₋ₓO), or cadmium zinc oxide (CdₓZn₁₋ₓO). Note that the Zn—O-based semiconductor may be a ZnO that may or may not be doped with at least one of impurity elements of, for example, Group 1 elements, Group 13 elements, Group 14 elements, Group 15 elements, and Group 17 element and that may be amorphous, polycrystalline, or microcrystal where a mixed combination of amorphous ZnO and polycrystalline ZnO is present.

The second gate electrode 20a overlaps the second channel region 16ac of the second semiconductor layer 16a and is configured so as to control conduction between the third conductive region 16aa and the fourth conductive region 16ab of the second semiconductor layer 16a, as shown in FIGS. 3 and 4.

The third terminal electrode 22c and the fourth terminal electrode 22d are electrically connected respectively to the third conductive region 16aa and the fourth conductive region 16ab of the second semiconductor layer 16a via a third contact hole Hc and a fourth contact hole Hd formed through the stack of the second interlayer insulating film 17, the third interlayer insulating film 19, and the fourth interlayer insulating film 21, as shown in FIGS. 3 and 4.

In the present embodiment, the third contact hole Hc and the fourth contact hole Hd are formed through the fourth interlayer insulating film 21 and then the third interlayer insulating film 19 (in this sequence when viewed from above), reaching the second interlayer insulating film 17 so as to expose at least a part of the surface of the third conductive region 16aa and the fourth conductive region 16ab of the second semiconductor layer 16a, as shown in FIGS. 3 and 4. Specifically, the third contact hole Hc and the fourth contact hole Hd are formed so as to overlap the third conductive region 16aa and the fourth conductive region 16ab in a plan view, reaching the third conductive region 16aa and the fourth conductive region 16ab. In other words, the third conductive region 16aa and the fourth conductive region 16ab are exposed inside the third contact hole Hc and the fourth contact hole Hd respectively. The exposed surfaces of the third conductive region 16aa and the fourth conductive region 16ab are formed on the top faces of the third conductive region 16aa and the fourth conductive region 16ab exposed in the bottom portions of the third contact hole Hc and the fourth contact hole Hd respectively.

Here, in the present embodiment, referring to FIGS. 3 and 4, a first metal layer 18a and a second metal layer 18b are provided so as to cover the exposed surfaces (top faces) of the third conductive region 16aa and the fourth conductive region 16ab of the second semiconductor layer 16a exposed inside the third contact hole Hc and the fourth contact hole Hd respectively. The first metal layer 18a and the second metal layer 18b are provided extending along the shape of the bottom portions of the third contact hole Hc and the fourth contact hole Hd from the top faces (exposed surfaces) of the third conductive region 16aa and the fourth conductive region 16ab, so as to straddle over the rims of the second interlayer insulating film 17 that extend around the third contact hole Hc and the fourth contact hole Hd, respectively. In other words, the first metal layer 18a and the second metal layer 18b are each shaped like an inverted hat in cross section that is contiguous on the top faces of the third conductive region 16aa and the fourth conductive region 16ab, on the surrounding faces (surrounding side face) of the second interlayer insulating film 17 around the third contact hole Hc and the fourth contact hole Hd, and on the top face of the second interlayer insulating film 17 around the third contact hole Hc and the fourth contact hole Hd.

In addition, in the third contact hole Hc and the fourth contact hole Hd, the first metal layer 18a and the second metal layer 18b are interposed between the exposed surfaces of the third conductive region 16aa and the fourth conductive region 16ab and the third terminal electrode 22c and the fourth terminal electrode 22d and are in contact with both of them, respectively. In other words, the third terminal electrode 22c and the fourth terminal electrode 22d are electrically connected respectively to the third conductive region 16aa and the fourth conductive region 16ab of the second semiconductor layer 16a via the third contact hole Hc and the fourth contact hole Hd and the first metal layer 18a and the second metal layer 18b. This structure establishes respective contact paths electrically connecting the exposed surfaces of the third conductive region 16aa and the fourth conductive region 16ab to the first metal layer 18a and the second metal layer 18b and then to the third terminal electrode 22c and the fourth terminal electrode 22d, in this sequence.

Note that the first metal layer 18a and the second metal layer 18b are made of the same material, and provided in the same layer, as an upper conductive layer 18c (detailed later) of the capacitor 9h. The first metal layer 18a and the second metal layer 18b may be made of, for example, a metal material (including alloys) such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), or tin (Sn) (including alloys). The first metal layer 18a and the second metal layer 18b may be a metal monolayer film of any of these metal materials and may be a stacked metal film of, for example, Mo (top layer)/Al (middle layer)/Mo (bottom layer), Ti/Al/Ti, Al (top layer)/Ti (bottom layer), Cu/Mo, or Cu/Ti. Among these metal materials, molybdenum (Mo), which is resistant to hydrofluoric acid, is preferred. The first metal layer 18a and the second metal layer 18b are preferably made of a metal material that contains molybdenum (Mo) as a primary component. Note that the primary component in the present specification refers to a component that accounts for more than 50 mass % of the metal material that constitutes the first metal layer 18a and the second metal layer 18b. The first metal layer 18a and the second metal layer 18b have a thickness that is not limited in any particular manner, but that is, for example, approximately from 50 nm to 300 nm, both inclusive.

As described so far, in the present embodiment, the first metal layer 18a and the second metal layer 18b are provided respectively on the third conductive region 16aa and the fourth conductive region 16ab of the second semiconductor layer 16a that are exposed inside the bottom portions of the third contact hole Hc and the fourth contact hole Hd.

In addition, the present embodiment discusses a write TFT 9c, a drive TFT 9d, a power supply TFT 9e, and a light-emission control TFT 9f, which are all p-channel TFTs (detailed later), as an example of the four first TFTs 9A including the first semiconductor layer 12a of a polysilicon and also discusses an initialization TFT 9a, a compensation TFT 9b, and an anode discharge TFT 9g, which are all n-channel TFTs (detailed later), as an example of the three second TFTs 9B including the second semiconductor layer 16a of an oxide semiconductor (see FIG. 5). Note that the four first TFTs 9A including the first semiconductor layer 12a of a polysilicon may be n-channel TFTs. In addition, the equivalent circuit diagram in FIG. 5 denotes the first terminal electrode 22a and the second terminal electrode 22b of each TFT 9c, 9d, 9e, and 9f by a circled 1 and a circled 2 and denotes the third terminal electrode 22c and the fourth terminal electrode 22d of each TFT 9a, 9b, and 9g by a circled 3 and a circled 4. In addition, the equivalent circuit diagram in FIG. 5 shows a pixel circuit for the subpixel P located in row n, column m and also shows a part of a pixel circuit for the subpixel P located in row (n−1), column m. In addition, the equivalent circuit diagram in FIG. 5 shows that the power supply line 22g for supplying a high-voltage power supply ELVDD doubles as a first initialization power supply line. Alternatively, the power supply line 22g and the first initialization power supply line may be provided separately. In addition, the second initialization power supply line 20i is fed with the same voltage as a low-voltage power supply ELVSS. This is however not the only possible implementation of the disclosure. Alternatively, the second initialization power supply line 20i may be fed with a voltage that differs from the low-voltage power supply ELVSS and that can turn off an organic EL element 35 (detailed later).

Referring to FIG. 5, the initialization TFT 9a, in each subpixel P, is electrically connected at the gate electrode thereof to one of the gate lines 14g(n−1) of the preceding stage ((n−1)-th stage), at a third terminal electrode thereof to a lower conductive layer (first gate electrode 14a) of the capacitor 9h (detailed later) and to the gate electrode of the drive TFT 9d, and at a fourth terminal electrode thereof to the power supply line 22g.

Referring to FIG. 5, the compensation TFT 9b, in each subpixel P, is electrically connected at the gate electrode thereof to one of the gate lines 14g(n) of the current stage (n-th stage), at a third terminal electrode thereof to the gate electrode of the drive TFT 9d, and at a fourth terminal electrode thereof to a first terminal electrode of the drive TFT 9d.

Referring to FIG. 5, the write TFT 9c, in each subpixel P, is electrically connected at the gate electrode thereof to the gate line 14g(n) of the current stage (n-th stage), at a first terminal electrode thereof to an associated one of the source lines 22f, and at a second terminal electrode thereof to a second terminal electrode of the drive TFT 9d.

Referring to FIG. 5, the drive TFT 9d, in each subpixel P, is electrically connected at the gate electrode thereof to the third terminal electrodes of the initialization TFT 9a and the compensation TFT 9b, at the first terminal electrode thereof to the fourth terminal electrode of the compensation TFT 9b and to a second terminal electrode of the power supply TFT 9e, and at the second terminal electrode thereof to the second terminal electrode of the write TFT 9c and to a first terminal electrode of the light-emission control TFT 9f. Here, the drive TFT 9d is configured to control the electric current in the organic EL element 35. In addition, in the first TFT 9A, which is a part of the drive TFT 9d, the gate insulating film 13 is thicker than the second interlayer insulating film 17, and therefore the S value can be increased in the sub-threshold region of the Id-Vg characteristics to render the rising curve less steep. Hence, this configuration allows for reducing the amount of change in the electric current relative to the amount of change in the voltage in the first TFT 9A, which in turn enables restraining changes in the luminance of the organic EL element 35. The resultant drive TFT 9d exhibits suitable properties.

Referring to FIG. 5, the power supply TFT 9e, in each subpixel P, is electrically connected at the gate electrode thereof to the light-emission control line 14e of the current stage (n-th stage), at a first terminal electrode thereof to the power supply line 22g, and at the second terminal electrode therefore to the first terminal electrode of the drive TFT 9d.

Referring to FIG. 5, the light-emission control TFT 9f, in each subpixel P, is electrically connected at the gate electrode thereof to the light-emission control line 14e of the current stage (n-th stage), at the first terminal electrode thereof to the second terminal electrode of the drive TFT 9d, and at a second terminal electrode thereof to a first electrode 31 (detailed later) of the organic EL element 35 (detailed later).

Referring to FIG. 5, the anode discharge TFT 9g, each subpixel P, is electrically connected at the gate electrode thereof to the gate line 14g(n) of the current stage (n-th stage), at a third terminal electrode thereof to the first electrode 31 of the organic EL element 35, and at a fourth terminal electrode thereof to the second initialization power supply line 20i.

Referring to FIG. 3, the capacitor 9h includes, for example: the first gate electrode 14a as a lower conductive layer; the first interlayer insulating film 15 and the second interlayer insulating film 17 on the first gate electrode 14a; and the upper conductive layer 18c overlapping the first gate electrode 14a on the second interlayer insulating film 17. The upper conductive layer 18c is made of the same material, and provided in the same layer, as the first metal layer 18a and the second metal layer 18b. In addition, referring to FIG. 5, the capacitor 9h, in each subpixel P, is electrically connected at the lower conductive layer (first gate electrode 14a) thereof to the gate electrode of the drive TFT 9d and also to the third terminal electrodes of the initialization TFT 9a and the compensation TFT 9b and at the upper conductive layer 18c thereof to the third terminal electrode of the anode discharge TFT 9g, the second terminal electrode of the light-emission control TFT 9f, and the first electrode 31 of the organic EL element 35.

The planarization film 23 has a flat face in the display area D and is made of, for example, either an organic resin material such as a polyimide resin or an acrylic resin or a polysiloxane-based SOG (spin on glass) material.

Referring to FIG. 3, the organic EL element layer 40 includes: the plurality of organic EL element 35, as a plurality of light-emitting elements, arranged in a matrix to correspond to the plurality of subpixels P; and an edge cover 32 arranged like a lattice commonly to all the subpixels P so as to cover a peripheral end portion of the first electrode 31 in each organic EL element 35.

Referring to FIG. 3, the organic EL element 35, in each subpixel P, includes: the first electrode 31 on the planarization film 23 of the TFT layer 30a; the organic EL layer 33 on the first electrode 31; and a second electrode 34 on the organic EL layer 33.

The first electrode 31 is electrically connected to the second terminal electrode of the light-emission control TFT 9f in each subpixel P via a contact hole formed through the planarization film 23. In addition, the first electrode 31 has a function of injecting holes to the organic EL layer 33. In addition, the first electrode 31 is more preferably made of a material having a large work function to improve the efficiency of hole injection to the organic EL layer 33. Here, the first electrode 31 may be made of, for example, a metal material such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), or tin (Sn). Alternatively, the first electrode 31 may be made of, for example, an alloy such as an astatine-astatine oxide (At—AtO₂) alloy. Furthermore, the first electrode 31 may be made of, for example, an electrically conductive oxide such as tin oxide (SnO), zinc oxide (ZnO), indium tin oxide (ITO), or indium zinc oxide (IZO). Alternatively, the first electrode 31 may include a stack of a plurality of layers of any of these materials. Note that examples of the compound material having a large work function include indium tin oxide (ITO) and indium zinc oxide (IZO).

Referring to FIG. 5, the organic EL layer 33 includes a hole injection layer 1, a hole transport layer 2, a light-emitting layer 3, an electron transport layer 4, and an electron injection layer 5, which are provided on the first electrode 31 in this order.

The hole injection layer 1 is alternatively referred to as the anode buffer layer and has a function of bringing the energy levels of the first electrode 31 and the organic EL layer 33 clos to each other, to improve the efficiency of hole injection from the first electrode 31 to the organic EL layer 33. Here, the hole injection layer 1 is made of, for example, a triazole derivative, an oxadiazole derivative, an imidazole derivative, a polyaryl alkane derivative, a pyrazoline derivative, a phenylenediamine derivative, an oxazole derivative, a styrylanthracene derivative, a fluorenone derivative, a hydrazone derivative, or a stilbene derivative.

The hole transport layer 2 has a function of improving the efficiency of hole transport from the first electrode 31 to the organic EL layer 33. Here, the hole transport layer 2 is made of, for example, a porphyrin derivative, an aromatic tertiary amine compound, a styryl amine derivative, polyvinyl carbazole, poly-p-phenylene vinylene, polysilane, a triazole derivative, an oxadiazole derivative, an imidazole derivative, a polyaryl alkane derivative, a pyrazoline derivative, a pyrazolone derivative, a phenylenediamine derivative, an aryl amine derivative, an amine-substituted chalcone derivative, an oxazole derivative, a styrylanthracene derivative, a fluorenone derivative, a hydrazone derivative, a stilbene derivative, a hydrogenated amorphous silicon, a hydrogenated amorphous silicon carbide, zinc sulfide, or zinc selenide.

The light-emitting layer 3 is injected with holes and electrons from the first electrode 31 and the second electrode 34 respectively when the light-emitting layer 3 is under a voltage applied by the first electrode 31 and the second electrode 34. These holes and electrons recombine in the light-emitting layer 3. Here, the light-emitting layer 3 is made of a material that has a high luminous efficiency. Then, the light-emitting layer 3 is made of, for example, a metal oxinoid compound [8-hydroxy quinoline metal complex], a naphthalene derivative, an anthracene derivative, a diphenyl ethylene derivative, a vinyl acetone derivative, a triphenyl amine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styryl amine derivative, a bis(styryl)benzene derivative, a tris(styryl)benzene derivative, a perylene derivative, a perynone derivative, an amino pyrene derivative, a pyridine derivative, a rhodamine derivative, an acridine derivative, phenoxazone, a quinacridone derivative, rubrene, poly-p-phenylene vinylene, or polysilane.

The electron transport layer 4 has a function of efficiently transporting electrons to the light-emitting layer 3. Here, the electron transport layer 4 is made of, for example, an organic compound such as an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, or a metal oxinoid compound.

The electron injection layer 5 has a function of bringing the energy levels of the second electrode 34 and the organic EL layer 33 clos to each other, to improve the efficiency of electron injection from the second electrode 34 to the organic EL layer 33. This function enables lowering the drive voltage of the organic EL element 35. Note that the electron injection layer 5 is alternatively referred to as the cathode buffer layer. Here, the electron injection layer 5 is made of, for example, an inorganic alkali compound such as lithium fluoride (LiF), magnesium fluoride (MgF₂), calcium fluoride (CaF₂), strontium fluoride (SrF₂), or barium fluoride (BaF₂), aluminum oxide (Al₂O₃), or strontium oxide (SrO).

Referring to FIG. 3, the second electrode 34 is provided commonly to all the subpixels P so as to cover the organic EL layers 33 and the edge cover 32. In addition, the second electrode 34 has a function of injecting electrons to the organic EL layer 33. In addition, the second electrode 34 is more preferably made of a material that has a small work function to improve the efficiency of electron injection to the organic EL layer 33. Here, the second electrode 34 is made of, for example, silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), or lithium fluoride (LiF). Alternatively, the second electrode 34 may be made of, for example, an alloy such as a magnesium-copper (Mg—Cu) alloy, a magnesium-silver (Mg—Ag) alloy, a sodium-potassium (Na—K) alloy, an astatine-astatine oxide (At—AtO₂) alloy, a lithium-aluminum (Li—Al) alloy, a lithium-calcium-aluminum (Li—Ca—Al) alloy, or a lithium fluoride-calcium-aluminum (LiF—Ca—Al) alloy. Alternatively, the second electrode 34 may be made of, for example, an electrically conductive oxide such as tin oxide (SnO), zinc oxide (ZnO), indium tin oxide (ITO), or indium zinc oxide (IZO). In addition, the second electrode 34 may include a stack of layers of any of these materials. Note that examples of the material that has a small work function include magnesium (Mg), lithium (Li), lithium fluoride (LiF), a magnesium-copper (Mg—Cu) alloy, a magnesium-silver (Mg—Ag) alloy, a sodium-potassium (Na—K) alloy, a lithium-aluminum (Li—Al) alloy, a lithium-calcium-aluminum (Li—Ca—Al) alloy, and a lithium fluoride-calcium-aluminum (LiF—Ca—Al) alloy.

The edge cover 32 is made of, for example, an organic resin material such as a polyimide resin or an acrylic resin or a polysiloxane-based SOG material.

Referring to FIG. 3, the sealing film 45 covers the second electrode 34, includes a first inorganic sealing film 41, an organic sealing film 42, and a second inorganic sealing film 43, which are sequentially stacked on the second electrode 34, and has a function of protecting the organic EL layer 33 in the organic EL element layer 40 from, for example, water and oxygen.

The first inorganic sealing film 41 and the second inorganic sealing film 43 include, for example, an inorganic insulating film such as a silicon nitride film, a silicon oxide film, or a silicon oxynitride film.

The organic sealing film 42 is made of, for example, an organic resin material such as an acrylic resin, an epoxy resin, a silicone resin, a polyurea resin, a parylene resin, a polyimide resin, or a polyamide resin.

In the organic EL display device 50a structured as above, in each subpixel P, first of all, as the light-emission control line 14e is selected and deactivated, the organic EL element 35 is turned into a non-emissive state. In that non-emissive state, the gate line 14g(n−1) of the preceding stage is selected to feed a gate signal to the initialization TFT 9a via the gate line 14g(n−1), which turns on the initialization TFT 9a. Accordingly, the high-voltage power supply ELVDD on the power supply line 22g is applied to the capacitor 9h, and the drive TFT 9d is turned on. Hence, the capacitor 9h discharges, initializing the voltage across the gate electrode of the drive TFT 9d. Next, as the gate line 14g(n) of the current stage is selected and activated, the compensation TFT 9b and the write TFT 9c are turned on, and a prescribed voltage corresponding to the source signal transferred via the corresponding source line 22f is written to the capacitor 9h via the diode-connected drive TFT 9d. Furthermore, the anode discharge TFT 9g is turned on, so that an initialization signal is applied to the first electrode 31 of the organic EL element 35 via the second initialization power supply line 20i, thereby resetting the electric charge stored in the first electrode 31. Thereafter, the light-emission control line 14e is selected to turn on the power supply TFT 9e and the light-emission control TFT 9f, thereby feeding a drive current in accordance with a voltage across the gate electrode of the drive TFT 9d from the power supply line 22g to the organic EL element 35. In this manner, in each subpixel P in the organic EL display device 50a, the organic EL element 35 emits light with a luminance that is in accordance with the drive current to produce an image display.

Next, a description is given of a method of manufacturing the organic EL display device 50a in accordance with the present embodiment. The method of manufacturing the organic EL display device 50a includes a TFT layer formation step, an organic EL element layer formation step, and a sealing film formation step. The TFT layer formation step includes a base coat film formation step, a first semiconductor layer formation step, a gate insulating film formation step, a first gate electrode formation step, a doping step, a first interlayer insulating film formation step, a second semiconductor layer formation step, a second interlayer insulating film formation step, a contact hole formation step, a metal layer formation step, a third interlayer insulating film formation step, a second gate electrode formation step, a fourth interlayer insulating film formation step, an upper-portion contact hole formation step, a terminal electrode formation step, and a planarization film formation step.

### TFT Layer Formation Step

### Base Coat Film Formation Step

First, The base coat film 11 is formed by sequentially forming a silicon oxide film (to a thickness of approximately 250 nm) and a silicon nitride film (to a thickness of approximately 100 nm) by, for example, plasma CVD (chemical vapor deposition) on, for example, the resin substrate 10 formed on a glass substrate.

### First Semiconductor Layer Formation Step

An amorphous silicon film (having a thickness of approximately 50 nm) is formed by, for example, plasma CVD on the substrate on which the base coat film 11 has been formed, the amorphous silicon film is then crystallized by, for example, laser annealing to form a polysilicon film, and thereafter the polysilicon film is patterned to form the first semiconductor layer 12a.

### Gate Insulating Film Formation Step

A silicon oxide film (having a thickness of approximately 100 nm) is formed by, for example, plasma CVD on the (entire) surface of the substrate on which the first semiconductor layer 12a has been formed, to form the gate insulating film 13.

### First Gate Electrode Formation Step

A metal layer such as a molybdenum film (having a thickness of approximately 200 nm) is formed by, for example, sputtering on the substrate on which the gate insulating film 13 has been formed, and thereafter the metal layer is patterned, to form the first gate electrode 14a. Note that, for example, the gate line 14g, the light-emission control line 14e, and the lower conductive layer (first gate electrode 14a) that is a part of the capacitor 9h are also formed in forming the first gate electrode 14a.

### Doping Step

A part of the first semiconductor layer 12a is modified into a conductor by doping with, for example, phosphorus, boron, or other like impurity ions using the first gate electrode 14a as a mask, to form the first conductive region 12aa, the second conductive region 12ab, and the first channel region 12ac on the first semiconductor layer 12a.

### First Interlayer Insulating Film Formation Step

A silicon oxide film (approximately 100 nm) is formed by, for example, plasma CVD on the (entire) surface of the substrate in which a part of the first semiconductor layer 12a has been modified into a conductor, to form the first interlayer insulating film 15.

### Second Semiconductor Layer Formation Step

An oxide semiconductor film (having a thickness of approximately 30 nm) such as InGaZnO₄ is formed by, for example, sputtering on the surface of the substrate on which the first interlayer insulating film 15 has been formed (the surface of the substrate that is located farther away from the resin substrate 10 than is the first semiconductor layer 12a), and thereafter the oxide semiconductor film is patterned, to form the second semiconductor layer 16a.

### Second Interlayer Insulating Film Formation Step

A silicon oxide film (having a thickness of approximately 300 nm) is formed by, for example, plasma CVD on the (entire) surface of the substrate on which the second semiconductor layer 16a has been formed, to form the second interlayer insulating film 17.

### Contact Hole Formation Step

The second interlayer insulating film 17, the first interlayer insulating film 15, and the gate insulating film 13 are patterned sequentially from above in a suitable manner on the surface of the substrate on which the second interlayer insulating film 17 has been formed, to form contact holes in, for example, the first contact hole Ha, the second contact hole Hb, the third contact hole Hc, and the fourth contact hole Hd (hereinafter, may be referred to as “lower-portion contact holes”). In so doing, the first contact hole Ha and the second contact hole Hb are formed so as to reach the first conductive region 12aa and the second conductive region 12ab of the first semiconductor layer 12a, thereby exposing the top faces of these regions respectively. In addition, the third contact hole Hc and the fourth contact hole Hd are formed so as to reach the second semiconductor layer 16a (the third conductive region 16aa and the fourth conductive region 16ab formed in a fourth interlayer insulating film formation step that will be detailed later) and to expose these top faces respectively.

### Metal Layer Formation Step

A metal film such as a molybdenum film (having a thickness of approximately 200 nm) is formed by, for example, sputtering on the surface of the substrate on which the lower-portion contact holes have been formed, and thereafter the metal film is patterned, to form the first metal layer 18a and the second metal layer 18b which cover the top faces (exposed surfaces) of the third conductive region 16aa and the fourth conductive region 16ab exposed inside the third contact hole Hc and the fourth contact hole Hd respectively. Note that the upper conductive layer 18c and other components that are parts of the capacitor 9h are also formed in forming the first metal layer 18a and the second metal layer 18b.

### Third Interlayer Insulating Film Formation Step

A silicon oxide film (having a thickness of approximately 300 nm) is formed by, for example, plasma CVD on the (entire) surface of the substrate in or on which the lower-portion contact holes, the first metal layer 18a, and the second metal layer 18b are formed, to form the third interlayer insulating film 19.

### Second Gate Electrode Formation Step

A metal film such as a molybdenum film (having a thickness of approximately 200 nm) is formed by, for example, sputtering on the surface of the substrate on which the third interlayer insulating film 19 has been formed, and thereafter the metal film is patterned, to form the second gate electrode 20a. Note that the second initialization power supply lines 20i are also formed in forming the second gate electrode 20a.

### Fourth Interlayer Insulating Film Formation Step

A silicon oxide film (having a thickness of approximately 300 nm) and a silicon nitride film (having a thickness of approximately 150 nm) are sequentially formed by, for example, plasma CVD on the (entire) surface of the substrate on which the second gate electrode 20a has been formed, to form the fourth interlayer insulating film 21. Note that the second semiconductor layer 16a is partly modified into a conductor by thermal treatment after the fourth interlayer insulating film 21 is formed, to form the third conductive region 16aa, the fourth conductive region 16ab, and the second channel region 16ac on the second semiconductor layer 16a.

### Upper-Portion Contact Hole Formation Step

The fourth interlayer insulating film 21 and the third interlayer insulating film 19 are patterned sequentially from above in a suitable manner on the surface of the substrate on which the fourth interlayer insulating film 21 has been formed, to form upper-portion contact holes that are contiguous to the lower-portion contact holes such as the first contact hole Ha, the second contact hole Hb, the third contact hole Hc, and the fourth contact hole Hd. Hence, the first contact hole Ha, the second contact hole Hb, the third contact hole Hc, and the fourth contact hole Hd, each of which is constituted by a lower-portion contact hole and an upper-portion contact hole, are completely formed.

Note that hydrofluoric-acid rinsing (hydrofluoric-acid rinsing step) is performed after the stack of the third interlayer insulating film 19 and the fourth interlayer insulating film 21 is patterned by dry etching, but before a terminal electrode formation step (detailed later), to remove a surface oxide film on the polysilicon film exposed in the bottom portions of the first contact hole Ha and the second contact hole Hb. The first contact hole Ha and the second contact hole Hb can be hence reliably formed which reach the first conductive region 12aa and the second conductive region 12ab of the first semiconductor layer 12a. In so doing, the surface of the second semiconductor layer 16a exposed inside the bottom portions of the third contact hole Hc and the fourth contact hole Hd, specifically, the top faces (exposed surfaces) of the third conductive region 16aa and the fourth conductive region 16ab are covered by the first metal layer 18a and the second metal layer 18b formed in the metal layer formation step respectively. Therefore, hydrofluoric-acid rinsing solution is restrained from coming into contact with the third conductive region 16aa and the fourth conductive region 16ab. In other words, the erosion (etching) of the InGaZnO₄ or other like oxide semiconductor film attributable to a hydrofluoric-acid rinsing solution is restrained, which in turn restrains, for example, oxide semiconductor film deficiency and breaks in the pattern.

### Terminal Electrode Formation Step

For example, a titanium film (having a thickness of approximately 50 nm), an aluminum film (having a thickness of approximately 400 nm), and a titanium film (having a thickness of approximately 50 nm) are sequentially formed by for example, sputtering on the surface of the substrate on which the first contact hole Ha and other contact holes have been formed, and thereafter, the stacked metal film is patterned, to form the first terminal electrode 22a, the second terminal electrode 22b, the third terminal electrode 22c, and the fourth terminal electrode 22d. Note that, for example, the source lines 22f and the power supply lines 22g are also formed in forming, for example, the first terminal electrode 22a.

### Planarization Film Formation Step

Finally, a polyimide-based photosensitive resin film (having a thickness of approximately 2 μm) is applied by, for example, spin-coating or slit-coating on the surface of the substrate on which, for example, the first terminal electrode 22a has been formed, and thereafter the coating film is pre-baked, exposed to light, developed, and post-baked to form the planarization film 23.

The TFT layer 30a is formed as described above.

### Organic EL Element Layer Formation Step

The first electrode 31, the edge cover 32, the organic EL layer 33 (the hole injection layer 1, the hole transport layer 2, the light-emitting layer 3, the electron transport layer 4, the electron injection layer 5), and the second electrode 34 are formed by a well-known method on the planarization film 23 of the TFT layer 30a formed in the aforementioned TFT layer formation step, to form the organic EL element layer 40.

### Sealing Film Formation Step

First, an inorganic insulating film such as a silicon nitride film, a silicon oxide film, or a silicon oxynitride film is formed by plasma CVD using a mask on the surface of the substrate on which the organic EL element layer 40 has been formed in the aforementioned organic EL element layer formation step, to form the first inorganic sealing film 41.

Subsequently, a film is formed of an organic resin material such as an acrylic resin by, for example, inkjet printing technology on the surface of the substrate on which the first inorganic sealing film 41 has been formed, to form the organic sealing film 42.

Thereafter, an inorganic insulating film such as a silicon nitride film, a silicon oxide film, or a silicon oxynitride film is formed by, for example, plasma CVD using a mask on the surface of the substrate on which the organic sealing film 42 has been formed, to form the second inorganic sealing film 43 and hence form the sealing film 45.

Finally, a protection sheet (not shown) is attached to the surface of the substrate on which the sealing film 45 has been formed, thereafter a laser beam is projected from the glass substrate side of the resin substrate 10, to lift off the glass substrate from the bottom face of the resin substrate 10, and a protection sheet (not shown) is attached to the bottom face of the resin substrate 10 from which the glass substrate has been lifted off.

The organic EL display device 50a in accordance with the present embodiment is manufactured as described above.

### Effects

As described above, according to the organic EL display device 50a in accordance with the present embodiment and the method of manufacturing the organic EL display device 50a, the following effects can be achieved.

In the organic EL display device 50a, the first metal layer 18a and the second metal layer 18b made of a metal material such as molybdenum (Mo) are provided covering the top faces (exposed surfaces) of the third conductive region 16aa and the fourth conductive region 16ab of the second semiconductor layer 16a exposed inside the bottom portions of the third contact hole Hc and the fourth contact hole Hd respectively. Then, in the method of manufacturing the organic EL display device 50a, the metal layer formation step by which the first metal layer 18a and the second metal layer 18b are formed is performed before the terminal electrode formation step by which terminal electrodes are formed as source electrodes or drain electrodes, specifically, before the hydrofluoric-acid rinsing is performed. Therefore, the hydrofluoric-acid rinsing solution is restrained from coming into contact with the third conductive region 16aa and the fourth conductive region 16ab. In other words, the erosion (etching) of the third conductive region 16aa and the fourth conductive region 16ab by the hydrofluoric-acid rinsing solution is restrained in the hydrofluoric-acid rinsing. Hence, inconveniences, for example, deficiencies in the InGaZnO₄ or another like oxide semiconductor film that is a part of the second semiconductor layer 16a and breaks in the pattern are less likely to develop, and normal signals can be fed to the second semiconductor layer 16a made primarily of an oxide semiconductor. As a result, manufacturing defects of the second TFTs 9B made primarily of an oxide semiconductor attributable to the hydrofluoric-acid rinsing can be restrained.

The method of manufacturing the organic EL display device 50a has been conceived by reviewing the known step sequence of the TFT layer formation step in which the first interlayer insulating film 15 is formed before forming the lower-portion contact holes, forming metal layers such as the upper conductive layer 18c of the capacitor 9h, and forming the second semiconductor layer 16a and by hence arriving at a step sequence of, first, providing a step of forming the second semiconductor layer 16a and forming the second interlayer insulating film 17, then forming the lower-portion contact holes, and forming the metal layers. By this step sequence, since the first metal layer 18a and the second metal layer 18b can be also formed in forming, for example, the upper conductive layer 18c of the capacitor 9h, the organic EL display device 50a, which exhibits the aforementioned effects, can be readily manufactured without having to performing complex steps.

### Second Embodiment

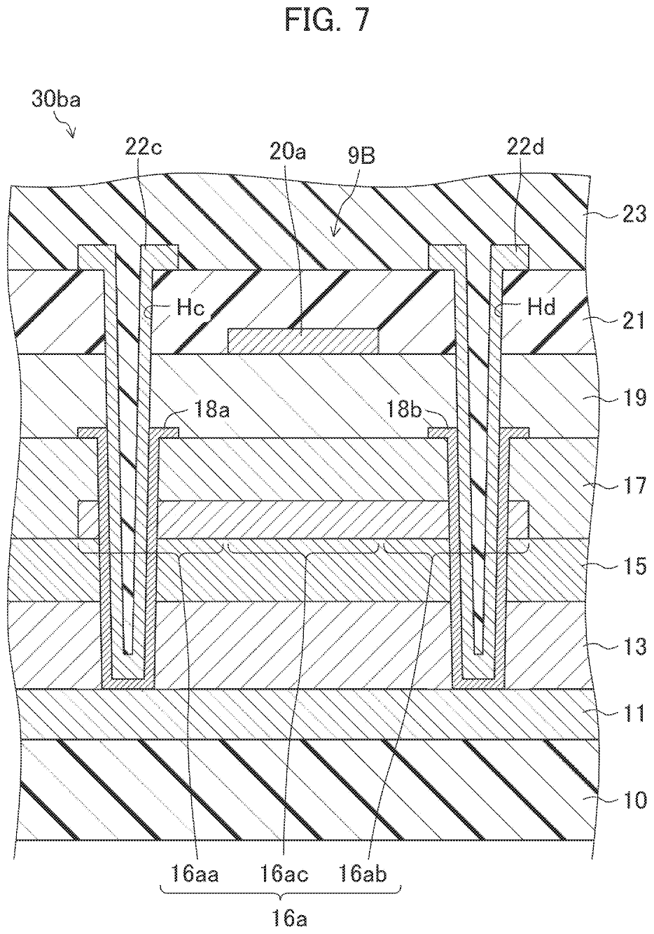

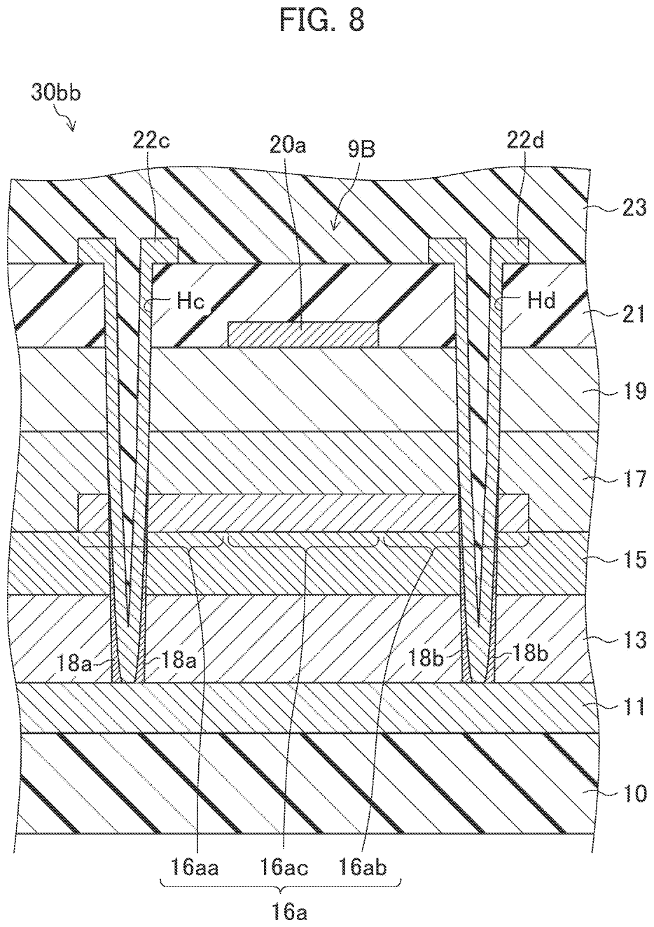

A description is given next of a second embodiment of the disclosure. FIGS. 7 and 8 illustrate a second embodiment of the display device in accordance with the disclosure. FIG. 7 is an enlarged cross-sectional view, which is an equivalent of FIG. 4, of a second TFT 9B and the surroundings thereof in a TFT layer 30ba that is a part of an organic EL display device 50b in accordance with the present embodiment. FIG. 8 is an enlarged cross-sectional view, which is an equivalent of FIG. 4, of a second TFT 9B and the surroundings thereof in a TFT layer 30bb that is a variation example of the TFT layer 30ba that is a part of the organic EL display device 50b in accordance with the present embodiment.

The overall structure of the organic EL display device 50b is the same as in the case of the first embodiment described above, except for the structure of the second TFTs 9B in the TFT layer 30ba and the TFT layer 30bb, and detailed description is omitted here. In addition, identical or equivalent members to those in the first embodiment are denoted by the same reference numerals, and their description may not be repeated.

In the second TFT 9B that is a part of the TFT layer 30ba in accordance with the present embodiment, as shown in FIG. 7, the third contact hole Hc and the fourth contact hole Hd are formed so as to run through the third conductive region 16aa and the fourth conductive region 16ab of the second semiconductor layer 16a respectively. Specifically, the third contact hole Hc and the fourth contact hole Hd are formed through the fourth interlayer insulating film 21, the third interlayer insulating film 19, the second interlayer insulating film 17, the third conductive region 16aa or the fourth conductive region 16ab, the first interlayer insulating film 15, and the gate insulating film 13 sequentially from above, to expose at least a part of the surface of the third conductive region 16aa and the fourth conductive region 16ab. In addition, the third contact hole Hc and the fourth contact hole Hd are formed so as to overlap the third conductive region 16aa and the fourth conductive region 16ab in a plan view similarly to the first embodiment described above. Hence, the exposed surfaces of the third conductive region 16aa and the fourth conductive region 16ab exposed inside the third contact hole Hc and the fourth contact hole Hd are formed on a surrounding face (surrounding side face) of the third conductive region 16aa and the fourth conductive region 16ab exposed from the outer circumferential surfaces of the third contact hole Hc and the fourth contact hole Hd respectively.

The first metal layer 18a and the second metal layer 18b, as shown in FIG. 7, are provided so as to cover the surrounding faces (exposed surfaces) of the third conductive region 16aa and the fourth conductive region 16ab respectively. Specifically, the first metal layer 18a and the second metal layer 18b are shaped like an inverted hat in cross section and provided extending along the shape of the third contact hole Hc and the fourth contact hole Hd from the bottom portions (bottom faces) of the third contact hole Hc and the fourth contact hole Hd, so as to straddle over the rims (surrounding top faces) of the second interlayer insulating film 17 that extend around the third contact hole Hc and the fourth contact hole Hd, respectively.

For the organic EL display device 50b, which includes the TFT layer 30ba in accordance with the present embodiment, the contact hole formation step is performed, for example, as in the following in the TFT layer formation step of the method of manufacturing the organic EL display device 50a in accordance with the first embodiment described above. The etched-out volume is adjusted (increased), and the first interlayer insulating film 15 and the gate insulating film 13 are removed by dry etching through the third conductive region 16aa and the fourth conductive region 16ab, to form the third contact hole Hc and the fourth contact hole Hd respectively.

### Variation Example of Second Embodiment

In the second TFT 9B, which is a part of the TFT layer 30bb in accordance with the present embodiment, as shown in FIG. 8, the first metal layer 18a and the second metal layer 18b may be post-patterning film remnants (residues) from the metal film provided on the second interlayer insulating film 17 in which the third contact hole Hc and the fourth contact hole Hd are formed. These film remnants extend along the surrounding side faces (surrounding side faces) of the third contact hole Hc and the fourth contact hole Hd and have upper ends thereof higher than the top faces of the third conductive region 16aa and the fourth conductive region 16ab. In other words, the exposed surfaces (surrounding faces) of the third conductive region 16aa and the fourth conductive region 16ab are covered by the first metal layer 18a and the second metal layer 18b formed as film remnants from the metal film.

For the organic EL display device 50b, which includes the TFT layer 30bb in accordance with the present embodiment, the metal layer formation step is performed, for example, as in the following in the TFT layer formation step of the method of manufacturing the organic EL display device 50a in accordance with the first embodiment described above. After a metal film is formed on the surface of the substrate on which the third contact hole Hc and the fourth contact hole Hd are formed, a resist is applied onto the metal film. Subsequently, the resist in the third contact hole Hc region and the fourth contact hole Hd region is exposed to light. Hence, resist remains along the rims of the bottom portions of the third contact hole Hc and the fourth contact hole Hd after the exposure to light. Thereafter, by etching the metal film using as a mask the residual resist that remains along the rims of the bottom portions of the third contact hole Hc and the fourth contact hole Hd, the first metal layer 18a and the second metal layer 18b are formed, which cover the exposed surfaces of the third conductive region 16aa and the fourth conductive region 16ab exposed inside the third contact hole Hc and the fourth contact hole Hd. In other words, the residual resist is thicker along the rims of the bottom portions of the third contact hole Hc and the fourth contact hole Hd, and therefore the metal film partially remains along the rims of the bottom portions after the etching of the metal film. These film remnants form the first metal layer 18a and the second metal layer 18b. In such a case, the film remnants as the first metal layer 18a and the second metal layer 18b need only to be present on the exposed surfaces of the third conductive region 16aa and the fourth conductive region 16ab (so as to cover the exposed surfaces) and, as shown in FIG. 8, may form films in parts of the bottom portions of the third contact hole Hc and the fourth contact hole Hd.

### Effects

As described above, according to the organic EL display device 50b in accordance with the present embodiment, the variation examples thereof, and the method of manufacturing the organic EL display device 50b and the variation examples, effects that are similar to those described above can be achieved. In other words, even when the third contact hole Hc and the fourth contact hole Hd run through the third conductive region 16aa and the fourth conductive region 16ab to form exposed surfaces on the surrounding faces of the third conductive region 16aa and the fourth conductive region 16ab, the exposed surfaces, which are covered by the first metal layer 18a and the second metal layer 18b, are restrained from coming into contact with the hydrofluoric-acid rinsing solution.

In addition, referring to FIGS. 7 and 8, the third terminal electrode 22c and the fourth terminal electrode 22d are formed on the first metal layer 18a and the second metal layer 18b formed along the surrounding side faces of the third contact hole Hc and the fourth contact hole Hd. Therefore, when compared with a case where the first metal layer 18a and the second metal layer 18b are missing, the steps formed on the surfaces of the third contact hole Hc and the fourth contact hole Hd that will serve as a base in forming the third terminal electrode 22c and the fourth terminal electrode 22d become more gentle, enabling restraining breaks in the third terminal electrode 22c and the fourth terminal electrode 22d, which is an additional advantage.

According to the variation examples of the organic EL display device 50b in accordance with the present embodiment and the method of manufacturing thereof, the first metal layer 18a and the second metal layer 18b are formed by etching the metal film using as a mask the residual resist that remains along the rims of the bottom portions of the third contact hole Hc and the fourth contact hole Hd. Therefore, no photomask is advantageously needed for forming the first metal layer 18a and the second metal layer 18b.

### Third Embodiment

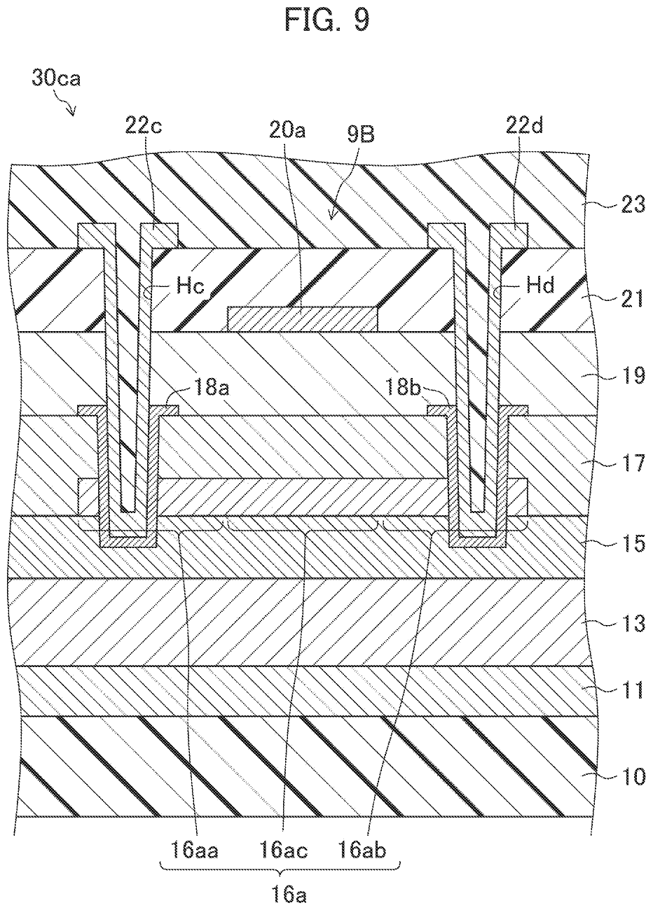

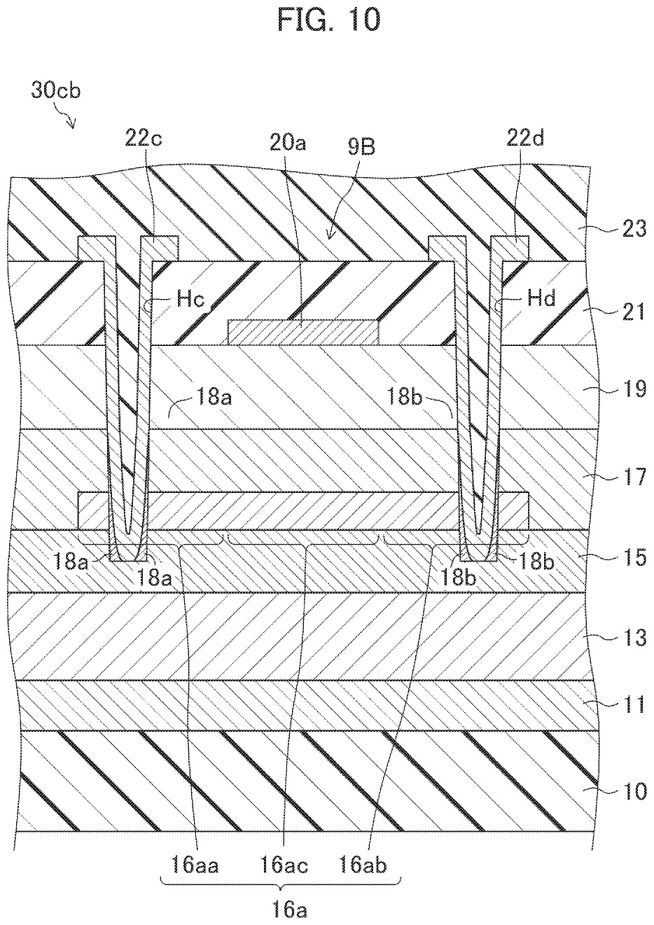

A description is given next of a third embodiment of the disclosure. FIGS. 9 and 10 illustrate the third embodiment of the display device in accordance with the disclosure. FIG. 9 is an enlarged cross-sectional view, which is an equivalent of FIG. 4, of a second TFT 9B and the surroundings thereof in a TFT layer 30ca that is a part of an organic EL display device 50c in accordance with the present embodiment. FIG. 10 is an enlarged cross-sectional view, which is an equivalent of FIG. 4, of a second TFT 9B and the surroundings thereof in a TFT layer 30cb that is a variation example of the TFT layer 30ca that is a part of the organic EL display device 50c in accordance with the present.

The overall structure of the organic EL display device 50c is the same as in the case of the first and second embodiments described above, except for the structure of the second TFT 9B that is a part of the TFT layer 30ca and the TFT layer 30cb, and detailed description is omitted here. In addition, identical or equivalent members to those in the first and second embodiments are denoted by the same reference numerals, and their description may not be repeated.

In the second TFT 9B that is a part of the TFT layer 30ca in accordance with the present embodiment, similarly to the TFT layer 30ba in accordance with the second embodiment described above, as shown in FIG. 9, the third contact hole Hc and the fourth contact hole Hd are formed through the third conductive region 16aa and the fourth conductive region 16ab of the second semiconductor layer 16a respectively. Meanwhile, in the TFT layer 30ca, the third contact hole Hc and the fourth contact hole Hd have a different depth (bottom portion position) when compared with the TFT layer 30ba. Specifically, the third contact hole Hc and the fourth contact hole Hd that are parts of the TFT layer 30ca are formed to run through the fourth interlayer insulating film 21, the third interlayer insulating film 19, the second interlayer insulating film 17, and either the third conductive region 16aa or the fourth conductive region 16ab sequentially from above, reaching the middle portion in the thickness direction of the first interlayer insulating film 15. Note that FIG. 9 shows the bottom portions of the third contact hole Hc and the fourth contact hole Hd being inside the first interlayer insulating film 15. Alternatively, the third contact hole Hc and the fourth contact hole Hd may be formed so that the bottom portions extend through the first interlayer insulating film 15 and reside inside the gate insulating film 13 (e.g., approximately the middle portion in the thickness direction of the gate insulating film 13).

For the organic EL display device 50c, which includes the TFT layer 30ca in accordance with the present embodiment, in the contact hole formation step in the TFT layer formation step in the method of manufacturing the organic EL display device 50b including the TFT layer 30ba in accordance with the second embodiment described above, for example, the etched-out volume may be reduced. Specifically, the third contact hole Hc and the fourth contact hole Hd may be formed by removing the first interlayer insulating film 15 through the third conductive region 16aa and the fourth conductive region 16ab to the middle portion in the thickness direction of the first interlayer insulating film 15 by dry etching.

### Variation Example of Third Embodiment

In the second TFT 9B, which is a part of the TFT layer 30cb in accordance with the present embodiment, similarly to the TFT layer 30bb in accordance with the second embodiment described above, as shown in FIG. 10, the first metal layer 18a and the second metal layer 18b are formed of post-patterning film remnants (residues) from the metal film provided on the second interlayer insulating film 17 in which the third contact hole Hc and the fourth contact hole Hd are formed. Meanwhile, in the TFT layer 30cb, the third contact hole Hc and the fourth contact hole Hd have a different depth (bottom portion position) when compared with the TFT layer 30bb. The bottom portion positions of the third contact hole Hc and the fourth contact hole Hd, which are parts of the TFT layer 30cb, are the same as is the case with the TFT layer 30ca.

For the organic EL display device 50c, which includes the TFT layer 30cb in accordance with the present embodiment, a step needs only to be performed that is similar to the TFT layer formation step of the method of manufacturing the organic EL display device 50b, which includes the TFT layer 30bb in accordance with the second embodiment described above.

### Effects

As described above, according to the organic EL display device 50c in accordance with the present embodiment, the variation examples thereof, and the method of manufacturing the organic EL display device 50c and the variation examples thereof, effects can be achieved that are similar to those achieved in the second embodiment described above. In other words, even when the etched-out volume in forming the third contact hole Hc and the fourth contact hole Hd is low (the third contact hole Hc and the fourth contact hole Hd have a shallow depth) when compared with the second embodiment, a solution can be used that is similar to the solution employed in the second embodiment.

### Other Embodiments

The foregoing embodiments have discussed examples where the organic EL layer has a 5-layer structure that includes a hole injection layer, a hole transport layer, a light-emitting layer, an electron transport layer, and an electron injection layer. Alternatively, the organic EL layer may have, for example, a 3-layer structure that includes a hole injection and transport layer, a light-emitting layer, and an electron transport and injection layer.

The foregoing embodiments have discussed examples where the organic EL display device includes a first electrode as an anode and a second electrode as a cathode. The disclosure is equally applicable to organic EL display devices in which the layered structure of the organic EL layer is reversed, to include a first electrode as a cathode and a second electrode as an anode.

The forgoing embodiments have discussed organic EL display devices as an example of the display device. The disclosure is equally applicable to display devices including liquid crystal display devices that operate by an active matrix driving scheme.

The foregoing embodiments have discussed resin substrates as an example of the substrate (base substrate). Alternatively, the substrate may be, for example, a glass substrate.

The foregoing embodiments have discussed display devices including a first TFT and a second TFT in each subpixel in the display area. The disclosure is equally applicable to display devices including, for example, a combination of a p-channel first TFT and a n-channel second TFT forming a CMOS (complementary metal oxide semiconductor), with the first TFT and the second TFT serving as a drive circuit in the frame area.

The foregoing embodiments have discussed organic EL display devices as an example of the display device. The disclosure is equally applicable to display devices including a plurality of current-driven light-emitting elements, for example, applicable to display devices including QLEDs (quantum-dot light-emitting diodes) which are light-emitting elements using a quantum-dot-containing layer.

### INDUSTRIAL APPLICABILITY

As described above, the disclosure is useful in flexible display devices.

1. A display device comprising:
a substrate; and
a thin film transistor layer on the substrate,
the thin film transistor layer including, in each subpixel:
a first thin film transistor including a first semiconductor layer of a polysilicon; and
a second thin film transistor including a second semiconductor layer of an oxide semiconductor, wherein
the second thin film transistor includes:
the second semiconductor layer on a first interlayer insulating film farther away from the substrate than is the first semiconductor layer;
a second interlayer insulating film covering the second semiconductor layer;
a terminal electrode; and
a contact hole exposing at least a part of the second semiconductor layer,
a metal layer is provided covering an exposed surface of the second semiconductor layer exposed inside the contact hole, and
the terminal electrode is electrically connected to the second semiconductor layer via the contact hole and the metal layer.

2. The display device according to claim 1, wherein
the thin film transistor layer includes a capacitor in each subpixel,
the capacitor includes:
a lower conductive layer;
the first interlayer insulating film covering the lower conductive layer;
the second interlayer insulating film on the first interlayer insulating film; and
an upper conductive layer provided on the second interlayer insulating film and overlapping the lower conductive layer, and
the metal layer is made of a same material, and provided in a same layer, as the upper conductive layer.

3. The display device according to claim 1, wherein the metal layer is made of a metal material containing primary of molybdenum.

4. The display device according to claim 1, wherein
the first thin film transistor includes:
the first semiconductor layer including a first conductive region and a second conductive region at a distance from each other;
a gate insulating film covering the first semiconductor layer;
a first gate electrode on the gate insulating film, the first gate electrode being configured to control conduction between the first conductive region and the second conductive region;
the first interlayer insulating film covering the first gate electrode;
a first terminal electrode and a second terminal electrode at a distance from each other; and
a first contact hole and a second contact hole exposing the first conductive region and the second conductive region respectively, wherein in the second thin film transistor,
the second semiconductor layer includes a third conductive region and a fourth conductive region at a distance from each other,
a third interlayer insulating film is provided on the second interlayer insulating film,
a second gate electrode is provided on the third interlayer insulating film, the second gate electrode being configured to control conduction between the third conductive region and the fourth conductive region,
a fourth interlayer insulating film is provided covering the second gate electrode,
the terminal electrode includes a third terminal electrode and a fourth terminal electrode at a distance from each other,
the contact hole includes a third contact hole and a fourth contact hole exposing the third conductive region and the fourth conductive region respectively,
the metal layer includes a first metal layer and a second metal layer covering exposed surfaces of the third conductive region and the fourth conductive region exposed inside the third contact hole and the fourth contact hole respectively,
the first terminal electrode, the second terminal electrode, the third terminal electrode, and the fourth terminal electrode are provided on the fourth interlayer insulating film,
the first terminal electrode and the second terminal electrode are electrically connected respectively to the first conductive region and the second conductive region via the first contact hole and the second contact hole, and
the third terminal electrode and the fourth terminal electrode are electrically connected respectively to the third conductive region and the fourth conductive region via the third contact hole and the fourth contact hole and also via the first metal layer and the second metal layer respectively.

5. The display device according to claim 4, wherein the third contact hole and the fourth contact hole are formed overlapping the third conductive region and the fourth conductive region respectively in a plan view.

6. The display device according to claim 4, wherein
the third contact hole and the fourth contact hole are formed through a stack of the second interlayer insulating film, the third interlayer insulating film, and the fourth interlayer insulating film,
the exposed surfaces of the third conductive region and the fourth conductive region are formed respectively on top faces of the third conductive region and the fourth conductive region exposed from bottom portions of the third contact hole and the fourth contact hole, and
the first metal layer and the second metal layer are provided so as to straddle over a rim of the second interlayer insulating film extending along the third contact hole and the fourth contact hole from the top faces of the third conductive region and the fourth conductive region respectively.

7. The display device according to claim 4 or 5, wherein
the third contact hole and the fourth contact hole are formed through the third conductive region and the fourth conductive region respectively,
the exposed surfaces of the third conductive region and the fourth conductive region are formed respectively surrounding faces of the third conductive region and the fourth conductive region exposed from surrounding side faces of the third contact hole and the fourth contact hole, and
the first metal layer and the second metal layer are provided covering the surrounding faces of the third conductive region and the fourth conductive region respectively.

8. The display device according to claim 7, wherein the first metal layer and the second metal layer are provided so as to straddle over a rim of the second interlayer insulating film extending along the third contact hole and the fourth contact hole from bottom portions of the third contact hole and the fourth contact hole respectively.

9. The display device according to claim 7, wherein the first metal layer and the second metal layer are post-patterning film remnants from a metal film provided on the second interlayer insulating film.

10. The display device according to claim 7, wherein the third contact hole and the fourth contact hole are formed through the gate insulating film.

11. The display device according to claim 4, wherein the thin film transistor layer includes a planarization film covering the first terminal electrode, the second terminal electrode, the third terminal electrode, and the fourth terminal electrode.

12. The display device according to claim 1, further comprising:
a light-emitting element layer including a plurality of light-emitting elements on the thin film transistor layer; and
a sealing film covering the light-emitting element layer.

13. The display device according to claim 12, wherein the plurality of light-emitting elements are organic electroluminescence elements.

14. A method of manufacturing a display device including: a substrate; and a thin film transistor layer on the substrate, the thin film transistor layer including, in each subpixel: a first thin film transistor including a first semiconductor layer of a polysilicon; and a second thin film transistor including a second semiconductor layer of an oxide semiconductor, the method comprising:
a second semiconductor layer formation step of forming the second semiconductor layer on a first interlayer insulating film farther away from the substrate than is the first semiconductor layer;
a second interlayer insulating film formation step of forming a second interlayer insulating film covering the second semiconductor layer;
a contact hole formation step of forming a contact hole exposing at least a part of the second semiconductor layer;
a metal layer formation step of forming a metal layer covering an exposed surface of the second semiconductor layer exposed inside the contact hole, by forming a metal film on the second interlayer insulating film through which the contact hole has been formed and subsequently patterning the metal film; and
a terminal electrode formation step of forming a terminal electrode electrically connected to the second semiconductor layer via the contact hole and the metal layer.

15. The method according to claim 14, wherein in the second thin film transistor,
the second semiconductor layer includes: a third conductive region and a fourth conductive region at a distance from each other; and a second channel region between the third conductive region and the fourth conductive region,
a third interlayer insulating film is provided on the second interlayer insulating film,
a second gate electrode is provided on the third interlayer insulating film, the second gate electrode being configured to control conduction between the third conductive region and the fourth conductive region,
a fourth interlayer insulating film is provided covering the second gate electrode,
in the contact hole formation step, as the contact hole, a third contact hole and a fourth contact hole are formed reaching the third conductive region and the fourth conductive region and exposing the third conductive region and the fourth conductive region respectively, and
in the metal layer formation step, as the metal layer, a first metal layer and a second metal layer are formed covering exposed surfaces of the third conductive region and the fourth conductive region exposed inside the third contact hole and the fourth contact hole respectively,
the method further comprising, following the metal layer formation step:
a third interlayer insulating film formation step of forming a third interlayer insulating film on the second interlayer insulating film;
a second gate electrode formation step of forming the second gate electrode on the third interlayer insulating film;
a fourth interlayer insulating film formation step of forming the fourth interlayer insulating film on the second gate electrode; and
an upper-portion contact hole formation step of forming an upper-portion contact hole contiguous to the third contact hole and the fourth contact hole, wherein
in the terminal electrode formation step, which follows the upper-portion contact hole formation step, a third terminal electrode and a fourth terminal electrode are formed as the terminal electrode on the fourth interlayer insulating film, the third terminal electrode and the fourth terminal electrode being electrically connected respectively to the third conductive region and the fourth conductive region via the third contact hole and the fourth contact hole and also via the first metal layer and the second metal layer respectively.

16. A method of manufacturing a display device including: a substrate; and a thin film transistor layer on the substrate, the thin film transistor layer including, in each subpixel: a first thin film transistor including a first semiconductor layer of a polysilicon; and a second thin film transistor including a second semiconductor layer of an oxide semiconductor, the method comprising:
a second semiconductor layer formation step of forming the second semiconductor layer on a first interlayer insulating film farther away from the substrate than is the first semiconductor layer;
a second interlayer insulating film formation step of forming a second interlayer insulating film covering the second semiconductor layer;
a contact hole formation step of forming a contact hole exposing at least a part of the second semiconductor layer;
a metal layer formation step of forming a metal layer covering an exposed surface of the second semiconductor layer exposed inside the contact hole, by forming a metal film on the second interlayer insulating film through which the contact hole has been formed, subsequently applying a resist onto the metal film, exposing the resist to light, and then etching the metal film using as a mask the resist that remains along a rim of a bottom portions of the contact hole; and
a terminal electrode formation step of forming a terminal electrode electrically connected to the second semiconductor layer via the contact hole and the metal layer.

17. The method according to claim 16, wherein in the second thin film transistor,
the second semiconductor layer includes: a third conductive region and a fourth conductive region at a distance from each other; and a second channel region between the third conductive region and the fourth conductive region,
a third interlayer insulating film is provided on the second interlayer insulating film,
a second gate electrode is provided on the third interlayer insulating film, the second gate electrode being configured to control conduction between the third conductive region and the fourth conductive region,
a fourth interlayer insulating film is provided covering the second gate electrode,
in the contact hole formation step, as the contact hole, a third contact hole and a fourth contact hole are formed extending through the third conductive region and the fourth conductive region and exposing the third conductive region and the fourth conductive region respectively, and
in the metal layer formation step, as the metal layer, a first metal layer and a second metal layer are formed covering exposed surfaces of the third conductive region and the fourth conductive region exposed inside the third contact hole and the fourth contact hole respectively,
the method further comprising, following the metal layer formation step:
a third interlayer insulating film formation step of forming a third interlayer insulating film on the second interlayer insulating film;
a second gate electrode formation step of forming the second gate electrode on the third interlayer insulating film;
a fourth interlayer insulating film formation step of forming the fourth interlayer insulating film on the second gate electrode; and
an upper-portion contact hole formation step of forming an upper-portion contact hole contiguous to the third contact hole and the fourth contact hole, wherein
in a terminal electrode formation step, which follows the upper-portion contact hole formation step, a third terminal electrode and a fourth terminal electrode are formed as the terminal electrode on the fourth interlayer insulating film, the third terminal electrode and the fourth terminal electrode being electrically connected respectively to the third conductive region and the fourth conductive region via the third contact hole and the fourth contact hole and also via the first metal layer and the second metal layer respectively.

18. The method according to claim 14, wherein
the first thin film transistor includes:
the first semiconductor layer on the base coat film, the first semiconductor layer including a first conductive region and a second conductive region at a distance from each other;
a gate insulating film covering the first semiconductor layer;
a first gate electrode on the gate insulating film, the first gate electrode being configured to control conduction between the first conductive region and the second conductive region;
the first interlayer insulating film covering the first gate electrode; and
a first terminal electrode and a second terminal electrode at a distance from each other, the first terminal electrode and the second terminal electrode being electrically connected respectively to the first conductive region and the second conductive region,
the method further comprising:
a first semiconductor layer formation step of forming the first semiconductor layer on the base coat film;
a gate insulating film formation step of forming the gate insulating film on the first semiconductor layer;
a first gate electrode formation step of forming the first gate electrode on the gate insulating film;
a doping step of forming the first conductive region, a first channel region, and a second conductive region by doping using the first gate electrode as a mask; and
a first interlayer insulating film formation step of forming the first interlayer insulating film on the first gate electrode, wherein
in the contact hole formation step, as the contact hole, a first contact hole and a second contact hole are formed reaching the first conductive region and the second conductive region respectively, and
in the terminal electrode formation step, the first terminal electrode and the second terminal electrode are formed as the terminal electrode.

19. The method according to claim 14, the method further comprising:
a planarization film formation step of forming a planarization film covering the terminal electrode;
a light-emitting element layer formation step of forming, on the planarization film, a light-emitting element layer including a plurality of light-emitting elements; and
a sealing film formation step of forming a sealing film covering the light-emitting element layer.

20. The method according to claim 19, wherein the plurality of light-emitting elements are organic electroluminescence elements.
